(19) United States
(12) Patent Application Publication
(10) Pub. No.: US 2025/0246428 A1
(43) Pub. Date: Jul. 31, 2025

(54) Anti-Reflective Layer for Protecting an N-Polar Group III-Nitride Semiconductor Structure

(71) Applicant: Wolfspeed, Inc., Durham, NC (US)

(72) Inventors: James Tajadod, Raleigh, NC (US); Fabian Radulescu, Chapel Hill, NC (US); Scott Sheppard, Chapel Hill, NC (US); James Scott Tweedie, Raleigh, NC (US)

(21) Appl. No.: 18/422,617

(22) Filed: Jan. 25, 2024

(51) Int. Cl. H01L 21/027; H01L 21/02; H01L 29/16; H01L 29/20

(52) U.S. Cl. CPC H01L 21/0276; H01L 21/0254; H10D 62/8325; H10D 62/8503

(57) ABSTRACT

Semiconductor structures including N-polar Group III-nitride are provided. The semiconductor structure includes an anti-reflective layer provided on an N-polar Group III-nitride semiconductor structure. The semiconductor structure includes a photoresist layer on the N-Polar Group III-nitride semiconductor structure. The anti-reflective layer has a thickness outside of an anti-reflectivity range associated with a photolithography process.

### FIELD

The present disclosure relates generally to semiconductor devices.

### BACKGROUND

Power semiconductor devices are widely used to carry large currents, support high voltages and/or operate at high frequencies such as radio frequencies. A wide variety of power semiconductor devices are available for different applications including, for example, power switching devices and power amplifiers. Many power semiconductor devices are implemented using various types of field effect transistors (FETs) devices including MOSFETs (metal-oxide semiconductor field-effect transistors), DMOS (double-diffused metal-oxide semiconductor) transistors, HEMTs (high electron mobility transistors), MESFETs (metal-semiconductor field-effect transistors), LDMOS (laterally diffused metal-oxide semiconductor) transistors, etc.

Power semiconductor devices may be fabricated from wide band gap semiconductor materials (e.g., having a band-gap greater than 1.40 eV). For example, power HEMTs may be fabricated from gallium nitride (GaN) or other Group III nitride-based material systems that are formed, for instance, on a silicon carbide (SiC) substrate or other substrate. As used herein, the term “Group III nitride” refers to those semiconducting compounds formed between nitrogen and the elements in Group III of the periodic table, usually aluminum (Al), gallium (Ga), and/or indium (In). These compounds have empirical formulas in which one mole of nitrogen is combined with a total of one mole of the Group III elements. For high power, high temperature, and/or high frequency applications, devices formed in wide band gap semiconductor materials such as silicon carbide (e.g., 2.996 eV band gap for alpha silicon carbide at room temperature) and the Group III-nitrides (e.g., 3.36 eV band gap for gallium nitride at room temperature) may provide higher electric field breakdown strengths and higher electron saturation velocities as compared to gallium arsenide (GaAs) and silicon (Si) based devices.

### SUMMARY

Aspects and advantages of embodiments of the present disclosure will be set forth in part in the following description, or may be learned from the description, or may be learned through practice of the embodiments.

One example embodiment of the present disclosure is directed to a semiconductor structure The semiconductor structure includes an N-Polar Group III-nitride semiconductor structure and an anti-reflective layer on the N-Polar Group III-nitride semiconductor structure. The semiconductor structure includes a photoresist layer on the N-Polar Group III-nitride semiconductor structure. The anti-reflective layer has a thickness in a range of about 85 nm to about 130 nm or has a thickness of greater than about 175 nm.

Another example embodiment of the present disclosure is directed to a semiconductor structure The semiconductor structure includes an N-Polar Group III-nitride semiconductor structure and an anti-reflective layer on the N-Polar Group III-nitride semiconductor structure. The semiconductor structure includes a photoresist layer on the N-Polar Group III-nitride semiconductor structure. The anti-reflective layer has a thickness outside an anti-reflective range associated with the photolithography process.

Another example embodiment of the present disclosure is directed to a method for processing an N-polar Group III-nitride semiconductor structure. The method includes providing an anti-reflective layer on an N-polar Group III-nitride semiconductor structure, the N-Polar Group III-nitride semiconductor structure comprising an N-polar Group III-nitride layer. The method includes providing a photoresist layer on the anti-reflective layer. The method includes conducting a photolithography process on the N-Polar Group III-nitride semiconductor structure to pattern the photoresist layer. The anti-reflective layer has a thickness outside an anti-reflective range associated with the photolithography process.

Another example embodiment of the present disclosure is directed to a method for processing an N-polar Group III-nitride semiconductor structure. The method includes providing an anti-reflective layer on an N-polar Group III-nitride semiconductor structure, the N-Polar Group III-nitride semiconductor structure comprising an N-polar Group III-nitride layer. The method includes providing a photoresist layer on the anti-reflective layer. The method includes conducting a photolithography process on the N-Polar Group III-nitride semiconductor structure to pattern the photoresist layer. The anti-reflective layer has a thickness of 85 nm to about 130 nm or has a thickness of greater than about 175 nm.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts example metal-polar and nitrogen-polar (N-polar) Group-III nitride crystal structures.

FIG. 2 depicts an example N-Polar Group III-nitride semiconductor structure and fabrication process;

FIG. 3 depicts an example transistor device having a semiconductor structure according to example embodiments of the present disclosure; and

FIG. 4 depicts a flow chart of an example method according to example embodiments of the present disclosure.

FIG. 5 depicts a graphical representation of anti-reflective properties of an example anti-reflective layer as a function of thickness of the anti-reflective layer.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor devices may be used in power electronics applications. For instance, transistor devices may be used in power electronics applications. Transistor devices, such as high electron mobility transistors (HEMTs) fabricated in Group III-nitride based material systems may have the potential to generate large amounts of radio frequency (RF) power because of the combination of material characteristics that includes high breakdown fields, wide band gaps, large conduction band offset, and/or high saturated electron drift velocity.

HEMT devices and other semiconductor devices may include metal-polar (e.g., Ga-polar) or nitrogen-polar (e.g., N-polar) N-Polar Group III-nitride semiconductor structures. More specifically, N-Polar Group III-nitride semiconductor structures may have a hexagonal wurtzite crystal structure that lacks inversion symmetry along a c-plane of the crystal structure. The lack of inversion symmetry may result in polarization effects. The polarization effects may lead to, for instance, a spontaneous polarization dipole in the N-Polar Group III-nitride semiconductor structure. The direction associated with the spontaneous polarization dipole is related to whether the Group III-nitride semiconductor structure is metal-polar or N-polar.

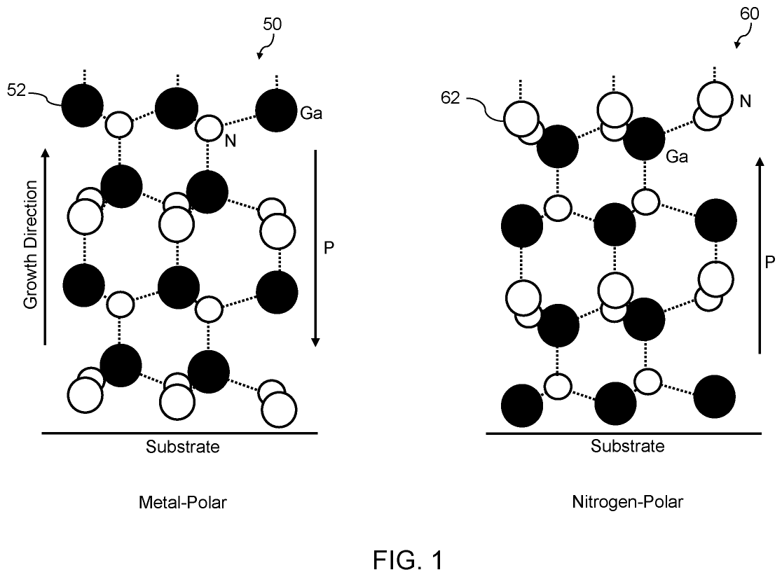

For instance, FIG. 1 depicts an example metal-polar Group III nitride semiconductor structure 50 (e.g., Ga-polar GaN) and an example N-Polar Group III-nitride semiconductor structure 60 (e.g., N-polar GaN). As shown, the metal-polar N-Polar Group III-nitride semiconductor structure 50 and the N-Polar Group III-nitride semiconductor structure 60 each have a hexagonal wurtzite crystal structure. In a wurtzite crystal structure, the metal (e.g., gallium) and the nitrogen are arranged in separate distinct layers. The metal-polar (e.g., Ga-polar) Group III-nitride semiconductor structure 50 has a metal face 52 (e.g., gallium face) in the growth direction of the semiconductor structure 50 relative to a substrate. However, metal-polar (e.g. Ga-polar) Group III-nitride semiconductor structures do not necessarily terminate in a metal face. The direction of the spontaneous polarization dipole P may be opposite the growth direction in the metal-polar N-Polar Group III-nitride semiconductor structure 50. The N-polar Group III-nitride semiconductor structure 60 has a nitrogen face 62 in the growth direction of the semiconductor structure 60 relative to a substrate. However, N-polar Group III-nitride semiconductor structures do not necessarily terminate in a nitrogen face. The direction of the spontaneous polarization dipole P may be the same as the growth direction in the N-Polar Group III-nitride semiconductor structure 60. HEMT devices including N-polar Group III-nitride structures have recently been shown to deliver significant performance advantages, particularly at operating frequencies in the millimeter wave frequency ranges (e.g., 30 GHz or greater) relative to traditional metal-polar Group-III nitride structures. N-polar surfaces have different levels of reactivity compared to metal-polar surfaces, which may require extra protection relative to metal-polar surfaces.

Chemistries involved in photolithography and stripping processes can be destructive to a sensitive N-polar Group III-nitride surface. For instance, solvents (e.g., developers) used to develop and pattern photoresist after exposure to radiation (e.g., light) might damage a sensitive N-polar Group III-nitride surface. In addition, etch and/or strip processes used to remove the photoresist may damage a sensitive N-polar Group III-nitride surface.

According to example aspects of the present disclosure, an anti-reflective layer can be used to protect an N-polar Group-III nitride surface from chemical degradation during a photolithography process during device fabrication. The anti-reflective coating may be an organic bottom anti-reflective coating (BARC). The use of the term “bottom” indicates that it may be applied under or prior to a photoresist layer in a photolithography process.

Anti-reflective coatings have been used in photolithography processes but have a very specific thickness range to provide anti-reflective properties for the radiation (e.g., light) exposed to a semiconductor structure during development of photoresist or other masking materials. According to examples of the present disclosure, anti-reflective coatings can have a thickness outside of an anti-reflective range associated with the photolithography process. The anti- reflective layer may be used to protect, seal, and/or insulate an N-polar Group III-nitride surface during subsequent photolithography and etch processes. As used herein, an anti-reflective coating has a thickness outside of its anti-reflective range for a photolithography process when it has a thickness associated with a reflectivity that is at least about 3% or greater for light or radiation used during the photolithography process.

Example aspects of the present disclosure provide technical effects and benefits. For instance, use of the anti-reflective layer outside of the thickness range associated with anti-reflective properties of the anti-reflective layer may reduce damage to N-polar Group III-nitride semiconductor layers during the fabrication of semiconductor devices. Reduced damage will increase integrity of semiconductor devices fabricated in the N-polar Group III-nitride semiconductor layers and preserve device performance. In addition, the use of the anti-reflective layer according to example embodiments of the present disclosure may lead to improved process uniformity and higher yield in semiconductor device fabrication.

Aspects of the present disclosure are discussed with reference to an HEMT device as an example semiconductor device having an N-polar Group III-nitride semiconductor layer for purposes of illustration and discussion. Those of ordinary skill in the art, using the disclosures provided herein, will understand that aspects of the present disclosure may be used with other semiconductor devices including an N-polar Group III-nitride semiconductor layer without deviating from the scope of the present disclosure.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

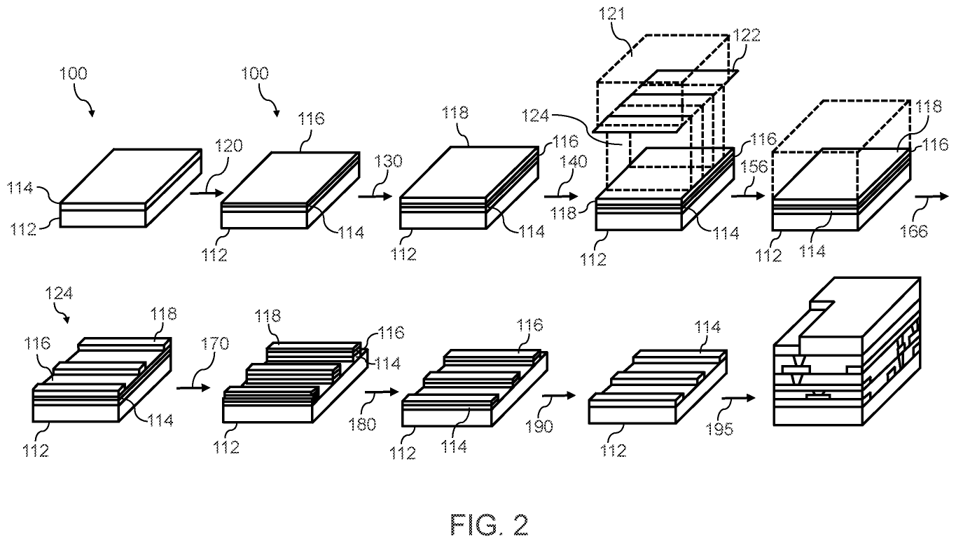

FIG. 2 depicts an example semiconductor structure 100 according to example embodiments of the present disclosure. FIG. 2 is intended to represent structures for identification and description and is not intended to represent the structures to physical scale. The semiconductor structure 100 includes a substrate 112, an N-polar Group III-nitride structure 114 on the substrate 112, and an anti-reflective layer 116 on the N-Polar Group III-nitride structure 114. For instance, at 120, the anti-reflective layer 116 can be provided on the N-Polar Group III-nitride structure 114.

The substrate 112 may be a semiconductor material. For instance, the substrate 112 may be a silicon substrate, a silicon carbide (SiC) substrate, a sapphire substrate, or other suitable substrate. In some embodiments, the substrate 112 may be a semi-insulating SiC substrate that may be, for example, the 4H polytype of SiC or may be the 3C, 6H, and 15R polytypes of SiC. The substrate 112 may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 112 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material in some examples, other examples of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. In some examples, the substrate 112 may have a thickness in a range of, for instance, about 50 μm to about 300 μm, such as in range of about 75 μm to about 200 μm, such as about 100 μm.

The N-Polar Group III-nitride semiconductor structure 114 may be provided on the substrate 112. For instance, in some examples, the N-Polar Group III-nitride semiconductor structure 114 may be formed and/or deposited using epitaxial growth, metal-organic chemical vapor deposition (MOCVD), molecular beam epitaxy (MBE), or hydride vapor phase epitaxy (HVPE). Techniques for epitaxial growth of Group III-nitrides have been described in, for example, U.S. Pat. Nos. 5,210,051, 5,393,993, and 5,523,589, the disclosures of which are incorporated by reference herein.

The N-Polar Group III-nitride semiconductor structure 114 may be a single layer structure or a multilayer structure. In the multilayer structure, each layer of the N-Polar Group III-nitride semiconductor structure may be a different Group III-nitride compound. As used herein, the term “Group III nitride” refers to those semiconducting compounds formed between nitrogen (N) and the elements in Group III of the periodic table, usually aluminum (Al), gallium (Ga), and/or indium (In). The term also refers to ternary and quaternary (or higher) compounds such as, for example, AlGaN and AlInGaN. As is well understood by those in this art, the Group III elements may combine with nitrogen to form binary (e.g., GaN), ternary (e.g., AlGaN, AlInN), and quaternary (e.g., AlInGaN) compounds. These compounds all have empirical formulas in which one mole of nitrogen is combined with a total of one mole of the Group III elements.

At 120, an anti-reflective layer 116 is provided on the N-Polar Group III-nitride semiconductor structure 114. In some embodiments, the anti-reflective layer 116 may be deposited on the N-Polar Group III-nitride semiconductor structure 114 using a CVD process(s), atomic layer deposition (ALD) process(s), sputter deposition process or other deposition process.

In some embodiments, the anti-reflective layer 116 can include one or more organic materials. In some examples, the anti-reflective layer 116 can include one or more of 2-(1-Methoxy) propyl acetate, ethyl 2-hydroxyisobutyrate, methyl lactate, one or more crosslinking agents, and/or polymer solids. In some examples, the anti-reflective layer 116 may be ARC i-CON™-7 manufactured by Brewer Science, Inc. However, other suitable anti-reflective coatings or materials may be used at the anti-reflective layer 116 without deviating from the scope of the present disclosure.

In some embodiments, the anti-reflective layer 116 has a thickness that is outside an anti-reflective range associated with a subsequent photolithography process. For instance, the anti-reflective layer 116 may not exhibit anti-reflective qualities when exposed to radiation during a photolithography process. For instance, while many anti-reflective layers are used to include certain materials and thicknesses to be anti-reflective during the photolithography process, aspects of the present disclosure contemplate use of an anti-reflective layer 116 for protection of the N-Polar Group III-nitride semiconductor structure 114. In some embodiments, the anti-reflective layer 116 can have a thickness that is outside of the range that imparts anti-reflective properties to the coating. For instance, the anti-reflective layer can have a thickness in a range from 85 nm to about 130 nm, such as about 90 nm to about 110 nm, such as about 100 nm. In some examples, the anti-reflective layer can have a thickness of greater than about 175 nm, such as in a range of about 175 nm to about 400 nm.

At 130, a photoresist layer 118 (e.g., mask) is provided on the anti-reflective layer 116. The photoresist layer 118 can include any suitable photoresist or masking components as known by those skilled in the art. The photoresist layer 118 can include a photosensitive agent in a polymer, solvent, or both. Additional additives can be added to the photoresist material as needed. For instance, the photoresist layer 118 may include a material that is capable of forming a pattern when the photoresist layer when exposed to radiation. Such a pattern is typically formed or indicated in the photoresist material via a photosensitive agent.

For instance, at 140 the structure 110 is exposed to radiation 121 (e.g., light, UV radiation, etc.) through mask 122. The mask 122 blocks radiation at certain locations on the photoresist layer 118 while allowing radiation to pass and expose the photoresist layer 118 to radiation at other locations, thus degrading portions of the photoresist layer 118 exposed to the radiation.

At 156 the photoresist layer 118 is developed by exposing the photoresist layer 118 to a solvent or developer. At 166, the solvent removes the degraded portions of the photoresist layer 118 resulting in the photoresist pattern 124 on the anti-reflective layer 116.

At 170, an etch process is performed in order to remove a portion of the anti-reflective layer 116 and the N-Polar Group III-nitride semiconductor structure 114 that are not protected by the developed photoresist layer 118. Any suitable etch process may be performed at 170, such as a plasma-based dry etch process or a wet etch process. Those of ordinary skill in the art, using the disclosure provided herein, will understand that aspects of the present disclosure can encompass any etch process at 170 without deviating from the scope of the present disclosure.

At 180, the remaining photoresist layer 118 can be removed (e.g., stripped) from the structure 100. Any suitable strip process may be performed at 180, such as a plasma-based dry strip process or a wet strip process. Those of ordinary skill in the art, using the disclosure provided herein, will understand that aspects of the present disclosure can encompass any strip process at 180 without deviating from the scope of the present disclosure.

At 190, any remaining anti-reflective layer 116 can also be removed (e.g., stripped) from the structure. Any suitable strip process may be performed at 190, such as a plasma-based dry strip process or a wet strip process. Those of ordinary skill in the art, using the disclosure provided herein, will understand that aspects of the present disclosure can encompass any strip process at 190 without deviating from the scope of the present disclosure.

After 190, the structure 100 includes a patterned N-Polar Group III-nitride semiconductor structure 114 provided on the substrate 112. Optionally, at 195 additional processing can be completed to provide a semiconductor structure 100 having additional layers and components fabricated therein. For instance, in embodiments, a semiconductor device can be fabricated at least partially in the N-Polar Group III-nitride semiconductor structure 114.

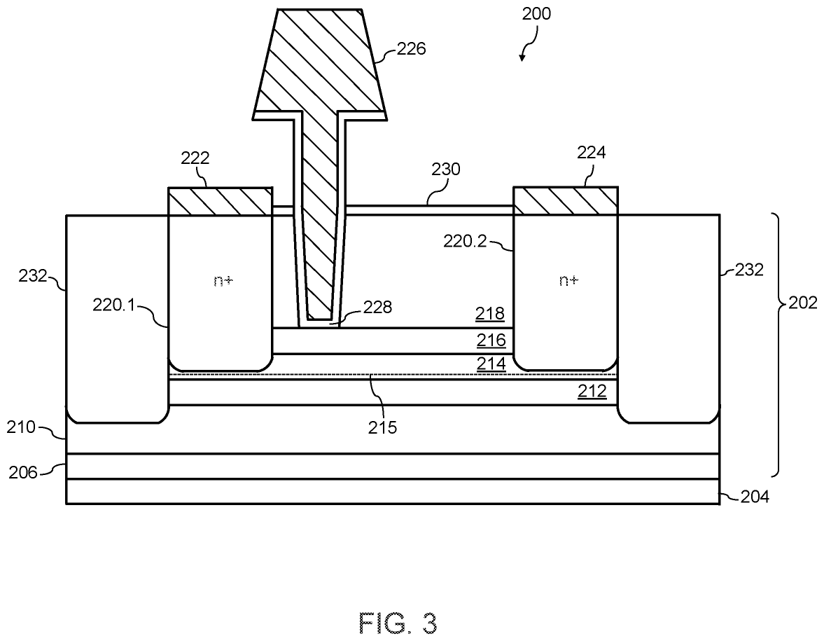

FIG. 3 depicts a cross-sectional view of an example HEMT device 200 that may be fabricated from an N-Polar Group III-nitride semiconductor structure (e.g., N-polar Group III-nitride semiconductor structure 114 of FIG. 2) according to example embodiments of the present disclosure. FIG. 3 is intended to represent structures for identification and description and is not intended to represent the structures to physical scale. The HEMT device 200 may include a semiconductor structure 202. The semiconductor structure 202 may be a Group III-nitride semiconductor structure, such as an N-polar Group III-nitride semiconductor structure.

The semiconductor structure 202 may be on a substrate 204. The substrate 204 may be a semiconductor material. For instance, the substrate 204 may be a silicon substrate, a silicon carbide (SiC) substrate, a sapphire substrate, or other suitable substrate. In some embodiments, the substrate 204 may be a semi-insulating SiC substrate that may be, for example, the 4H polytype of silicon carbide. Other SiC candidate polytypes may include the 3C, 6H, and 15R polytypes. The substrate may be a High Purity Semi-Insulating (HPSI) substrate, available from Wolfspeed, Inc. The term “semi-insulating” is used descriptively herein, rather than in an absolute sense.

In some embodiments, the SiC bulk crystal of the substrate 204 may have a resistivity equal to or higher than about 1×10⁵ ohm-cm at room temperature. Example SiC substrates that may be used in some embodiments are manufactured by, for example, Wolfspeed, Inc., and methods for producing such substrates are described, for example, in U.S. Pat. No. Re. 34,861, U.S. Pat. Nos. 4,946,547, 5,200,022, and 6,218,680, the disclosures of which are incorporated by reference herein. Although SiC may be used as a substrate material, embodiments of the present disclosure may utilize any suitable substrate, such as sapphire (Al₂O₃), aluminum nitride (AlN), aluminum gallium nitride (AlGaN), gallium nitride (GaN), silicon (Si), GaAs, LGO, zinc oxide (ZnO), LAO, indium phosphide (InP), and the like. The substrate 204 may be a SiC wafer, and the HEMT device 200 may be formed, at least in part, via wafer-level processing, and the wafer may then be diced to provide a plurality of individual HEMT devices 100. In some embodiments, the substrate 204 of the HEMT device 200 may be a thinned substrate 204. In some embodiments, the thickness of the substrate 204 may be about 100 μm or less, such as about 75 μm or less, such as about 50 μm or less.

The semiconductor structure 202 may include an optional nucleation layer 206 on the substrate 204. The nucleation layer 206 may be, for instance, a GaN layer and/or an AlN layer on the substrate 204 to provide a crystal structure transition between, for instance, a SiC substrate 104 and the Group III-nitride semiconductor structure 202. The nucleation layer 206 may be deposited on the substrate 204 using, for instance, metal-organic chemical vapor deposition (MOCVD), molecular beam epitaxy (MBE), or hydride vapor phase epitaxy (HVPE).

The semiconductor structure 202 may be an N-polar Group III-nitride semiconductor structure with an outward N-face in the growth direction 108 of the semiconductor structure 202. The semiconductor structure 202 may include several layers. In the example HEMT device 200 of FIG. 2, the semiconductor structure includes a buffer layer 210, a back barrier layer 212, a channel layer 214, a first cap layer 216, and a second cap layer 218. However, those of ordinary skill in the art, using the disclosures provided herein, will understand that aspects of the present disclosure are applicable to devices having semiconductor structures with different layer arrangements. The semiconductor structure 202 may be formed by epitaxial growth on the substrate 204. Techniques for epitaxial growth of Group III-nitrides have been described in, for example, U.S. Pat. Nos. 5,210,051, 5,393,993, and 5,523,589, the disclosures of which are incorporated by reference herein.

The buffer layer 210 may be an N-polar Group III nitride, such as AlᵥGa₁₋ᵥN, where 0≤v<0.1. In some embodiments, the aluminum mole fraction v is approximately 0 (e.g., 0.05 or less), indicating that the buffer layer 210 is GaN. The buffer layer 210 may or may not include other Group III-nitrides such as InGaN, AlInGaN or the like. The buffer layer 210 may be undoped or only unintentionally doped. In some examples, the buffer layer 210 may be iron doped to make the buffer layer semi-insulating. The buffer layer 210 may be grown to a thickness in the range of about 0.5 μm to about 5 μm, such as about 2 μm. The buffer layer 210 may be a multi-layer structure, such as a superlattice or combinations of GaN, AlGaN or the like. The buffer layer 210 may be under compressive strain in some embodiments.

The semiconductor structure 202 may include the back barrier layer 212 on the buffer layer 210. The back barrier layer 212 may be an N-polar Group III nitride, such as Al_{w}Ga_{1-w}N where 0.1≤w<0.4, indicating that the back barrier layer 212 is an AlGaN layer. In some embodiments, the back barrier layer 212 may be a ScAlN layer or a ScAlGaN layer. The back barrier layer 212 may or may not include other Group III-nitrides such as InGaN, AlInGaN or the like. The back barrier layer 212 may have a different band gap relative to the channel layer 214. The back barrier layer 212 may have a thickness in a range of about 250 Angstroms to about 350 Angstroms, such as about 300 Angstroms.

In some embodiments, the back barrier layer 212 may be a multilayer structure. For instance, in one example, the back barrier layer 212 may include a first layer of n+ doped GaN with a thickness of about 100 Angstroms. The back barrier layer 212 may include a second layer of graded Al_{w.1}Ga_{1-w.1}N on the first layer, where w.1 varies from about 0.05 to about 0.4. The second layer of graded Al_{w}Ga_{1-w}N may have a thickness of about 100 Angstroms. The back barrier layer 212 may include a third layer of Al_{w.2}Ga_{1-w.2}N on the second layer, where w.2 is in a range of 0.3 to 0.4. The thickness of the third layer may be about 100 Angstroms. The back barrier layer 212 may include a fourth layer of AlN on the third layer. The thickness of the fourth layer may be in a range of about 5 Angstroms to about 15 Angstroms, such as about 7 Angstroms.

The semiconductor structure 202 may include the channel layer 214 on the back barrier layer 212. The channel layer 214 may be an N-polar Group III-nitride, such as AlₓGa₁₋ₓN, where 0≤x<0.1, provided that the energy of the conduction band edge of the channel layer 214 is less than the energy of the conduction band edge of the back barrier layer 212 at the interface between the channel layer 214 and the back barrier layer 212. The channel layer 214 may have a band gap that is different than the band gap of the back barrier layer 212. In some embodiments, the aluminum mole fraction x is approximately 0 (e.g., 0.05 or less), indicating that the channel layer 214 is GaN. The channel layer 214 may or may not include other Group III-nitrides such as InGaN, AlInGaN or the like. The channel layer 214 may have a thickness in a range of about 75 Angstroms to about 125 Angstroms, such as about 100 Angstroms.

A 2DEG 215 may be induced in the channel layer 214 at the interface between the channel layer 214 and the back barrier layer 212. The 2DEG 215 is highly conductive and allows conduction between the source and drain regions of the HEMT device 200. The 2DEG 215 may be controlled under operation of a gate, such that the HEMT device 200 acts as a controllable transistor device.

The semiconductor structure 202 includes a first cap layer 216 (e.g., an AlGaN cap layer) on the channel layer 214. The first cap layer 216 may be an N-polar Group III-nitride, such as Al_{y}Ga_{1-y}N where 0.1Sy<0.4, indicating that the first cap layer 216 is an AlGaN layer. In some embodiments, the aluminum mole fraction y is in a range of about 0.2 to about 0.3. In some embodiments, the first cap layer 216 may be a ScAlN layer or a ScAlGaN layer. The first cap layer 216 may or may not include other Group III-nitrides such as InGaN, AlInGaN or the like. The first cap layer may have a band gap that is different than the band gap of the channel layer 214. The first cap layer 216 may have a thickness in a range of about 15 Angstroms to about 50 Angstroms, such as about 26 Angstroms.

The semiconductor structure 202 includes a second cap layer 218 on the first confining layer 216. The second cap layer 218 may be an N-polar Group III-nitride, such as Al_{z}Ga_{1-z}N, where 0≤z<0.1. In some embodiments, the aluminum mole fraction z is approximately 0 (e.g., 0.05 or less), indicating that the second cap layer 218 is a GaN layer. The second cap layer 218 may or may not include other Group III-nitrides such as InGaN, AlInGaN or the like. The second cap layer 218 buries the channel layer 214 deep below the surface of semiconductor structure 202 such that the channel layer 214 is a buried layer at a depth of about 275 Angstroms or greater from the surface of the semiconductor structure 202, such as about 500 Angstroms or greater from the surface of the semiconductor structure 202, such as in a range of about 275 Angstroms to about 1000 Angstroms from the surface of the semiconductor structure 102. The second cap layer 218 may have a thickness in a range of about 250 Angstroms to about 1000 Angstroms, such as about 500 Angstroms.

The semiconductor structure 202 includes implanted regions 220.1 and 220.2. The implanted regions 220.1 and 220.2 include a distribution of implanted dopants (e.g., ions) of a first conductivity type such that the implanted regions 220.1 and 220.2 are n-type regions. The implanted regions 220.1 and 220.2 extend through the semiconductor structure 202 and into the channel layer 214.

The HEMT device 200 includes electrodes on the implanted regions 220.1 and 220.2. More particularly, the HEMT device 200 may include a source contact 222 on the implanted region 220.1. The HEMT device 200 may include a drain contact 224 on the implanted region 220.2. The source contact 222 and the drain contact 224 may be laterally spaced apart from each other. In some embodiments, the source contact 222 and the drain contact 224 may include a metal that may form an ohmic contact to a Group III-nitride based semiconductor material. Suitable metals may include refractory metals, such as titanium (Ti), tungsten (W), titanium tungsten (TiW), silicon (Si), titanium tungsten nitride (TiWN), tungsten silicide (WSi), rhenium (Re), niobium (Nb), Ni, gold (Au), aluminum (Al), tantalum (Ta), molybdenum (Mo), NiSiₓ, titanium silicide (TiSi), titanium nitride (TiN), tungsten silicon nitride (WSiN), platinum (Pt) and the like. In some embodiments, the source contact 222 may be an ohmic contact. The drain contact 224 may be an ohmic contact. In some embodiments, the source contact 222 and/or the drain contact 224 may include a plurality of layers to form an ohmic contact that may be provided as described, for example, in U.S. Pat. Nos. 8,563,372 and 9,214,352, the disclosures of which are incorporated by reference herein.

The HEMT device 200 may include a gate contact 226. The gate contact 226 may extend at least partially through a trench (e.g., an ALE defined trench) in the second cap layer 218 so that the gate contact 226 is proximate to the first cap layer 216. In some examples, the gate contact 226 may have a gate length LG in a range of about 50 nm to about 150 nm. The gate length is the length of the gate contact 226 proximate to the first cap layer 216.

A passivation layer 228 may be located between the gate contact 226 and the first cap layer 216. The passivation layer 228 may be SiN. Other suitable dielectric layers may be used as the passivation layer 228, such as SiO₂, MgOx, MgNx, ZnO, SiNx, SiOx or other dielectric layers. The passivation layer 228 may be formed, for instance, using MOCVD process(s), atomic layer deposition (ALD) process(s), and/or sputter deposition processes. The passivation layer 128 may serve as a gate dielectric. In some examples, the passivation layer 228 may have a thickness, for instance, of about 5 Angstroms to about 100 Angstroms, such as about 10 Angstroms to about 50 Angstroms.

The gate contact 226 may be a T-shaped gate or a gamma gate, the formation of which is discussed by way of example in U.S. Pat. Nos. 8,049,252, 7,045,404, and 8,120,064, the disclosures of which are incorporated by reference herein. Materials capable of making a contact (e.g., a Schottky contact) to a Group III-nitride based semiconductor material may be used, such as, for example, nickel (Ni), platinum (Pt), nickel silicide (NiSiₓ), copper (Cu), palladium (Pd), chromium (Cr), tungsten (W) and/or tungsten silicon nitride (WSiN).

The HEMT device 200 may include additional passivation layer(s) 230 on the semiconductor structure 202, the gate contact 226, and/or other structures of the HEMT device 200. The additional passivation layer(s) 230 may be, for instance, dielectric materials, such as SiO₂, MgOx, MgNx, ZnO, SiNx, SiOx, alloys or layer sequences thereof. The additional passivation layer(s) 130 may be formed using MOCVD process(s), ALD process(s), sputter deposition process(s), or other suitable process(s). One or more insulating layers (not shown) may be on the HEMT device 100. For instance, the HEMT device 200 may be encapsulated in an insulating material without deviating from the scope of the present disclosure.

In some examples, the HEMT device 200 may be operable at frequencies of up to about 150 GHz. For instance, the HEMT device 200 may be operable at a frequency in a range of about 10 GHz to about 150 GHz, such as in a range of about 30 GHz to about 150 GHz, such as in a range of about 50 GHz to about 150 GHz. In some examples, the HEMT device 200 may have a power density of up to 10 W/mm or greater in these frequency ranges, such as a power density in a range of 2.5 W/mm to about 12 W/mm.

A transistor device cell may be formed by the active region between the source contact 222 and the drain contact 224 under the control of a gate contact 226 between the source contact 222 and the drain contact 224. FIG. 2 depicts a cross-sectional view of one device cell of an HEMT device 200 for purposes of illustration.

According to example aspects of the present disclosure, the HEMT device 200 may include an isolation implant region 232. The isolation implant region 232 may extend to a depth in the semiconductor structure 202 sufficient to provide electrical isolation between regions in a semiconductor device, such as a first region associated with a first transistor device cell (e.g., HEMT device cell) and a second region associated with a second transistor device cell (e.g., HEMT device cell).

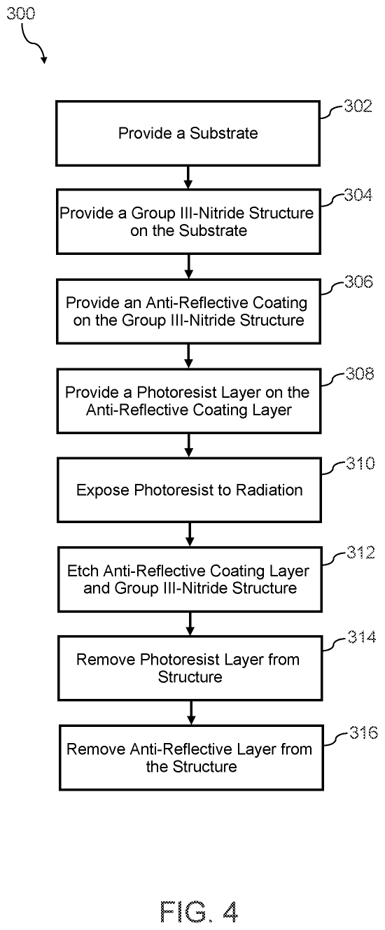

FIG. 4 depicts a flow chart of an example method 300 for fabricating a semiconductor device according to example embodiments of the present disclosure. FIG. 4 depicts example process steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 302, the method may include providing a substrate, such as a silicon carbide

substrate. The substrate may be, for instance, the substrate described with reference to FIG. 1. In some examples, the substrate may be a SiC substrate with a Si-face and a C-face.

At 304, the method 350 may include providing an N-polar Group III-nitride structure (e.g., layer) on the substrate. For instance, the N-Polar Group III-nitride structure can include an N-polar Group III-nitride layer that can be on the substrate.

The N-polar Group III-nitride structure can be epitaxially formed on the substrate. The N-Polar Group III-nitride semiconductor structure may be, for instance, the N-Polar Group III-nitride semiconductor structure described with reference to FIG. 1. The N-Polar Group III-nitride semiconductor structure may be formed on the substrate using, for instance, metal-organic chemical vapor deposition (MOCVD), molecular beam epitaxy (MBE), or hydride vapor phase epitaxy (HVPE). Techniques for epitaxial growth of Group III-nitrides have been described in, for example, U.S. Pat. Nos. 5,210,051, 5,393,993, and 5,523,589, the disclosures of which are incorporated by reference herein.

At 306, the method includes providing an anti-reflective layer on the N-Polar Group III-nitride semiconductor structure. For instance, the anti-reflective layer can include one or more organic materials. In some examples, the anti-reflective layer may include one or more of 2-(1-Methoxy) propyl acetate, ethyl 2-hydroxyisobutyrate, methyl lactate, one or more crosslinking agents, and/or polymer solids. In some examples, the anti-reflective layer 116 may be ARC i-CON™-7 manufactured by Brewer Science, Inc. However, other suitable anti-reflective coatings or materials may be used at the anti-reflective layer 116 without deviating from the scope of the present disclosure. The anti-reflective layer can include a thickness that is outside an anti-reflective range associate with a subsequent photolithography process. For instance, the anti-reflective layer can have a thickness that is not anti-reflective during exposure to radiation during a photolithography process. As noted, the anti-reflective layer as disclosed can be used to seal and protect the underlying N-Polar Group III-nitride semiconductor structure during subsequent processing. The anti-reflective layer can have a thickness in a range from about 85 nm to about 130 nm, such as about 90 nm to about 110 nm, such as about 100 nm. In some examples, the anti-reflective layer can have a thickness of greater than about 175 nm, such as in a range of about 175 nm to about 400 nm.

At 308, the method includes providing a photoresist layer on the anti-reflective layer. The photoresist layer can include any suitable masking or photoresist compositions as known to those of skill in the art.

At 310, the method includes exposing the photoresist layer to radiation to pattern the photoresist layer. For instance, portions of the photoresist layer can be exposed to radiation in order to provide a pattern thereon, which can also be developed to provide a photoresist pattern in the photoresist layer. Portions of the photoresist layer that are exposed to the radiation can be removed from the photoresist layer to create a photoresist pattern structure on the structure.

At 312, the method includes removing the anti-reflective layer and the N-Polar Group III-nitride semiconductor structure layer from the structure. For instance, portions of the anti-reflective layer and the N-Polar Group III-nitride semiconductor structure remaining under the photoresist pattern can remain while exposed portions of the anti-reflective layer and the N-Polar Group III-nitride semiconductor structure can be removed (e.g., etched). These material layers can be etched via known processes as know by those of skill in the art.

At 314, the method includes removing the remaining photoresist material from the structure. For instance, any suitable photoresist strip method can be utilized to remove any remaining photoresist material (e.g., masking material) remaining on the structure.

At 316, the method includes removing any remaining anti-reflective layer from the structure. The anti-reflective layer can be removed by any suitable strip or etch method known to those of skill in the art. Notably, after 316 the remaining structure includes a substrate having a patterned N-Polar Group III-nitride semiconductor structure provided thereon. The resulting structure can be further processed to include additional components and material layers as needed.

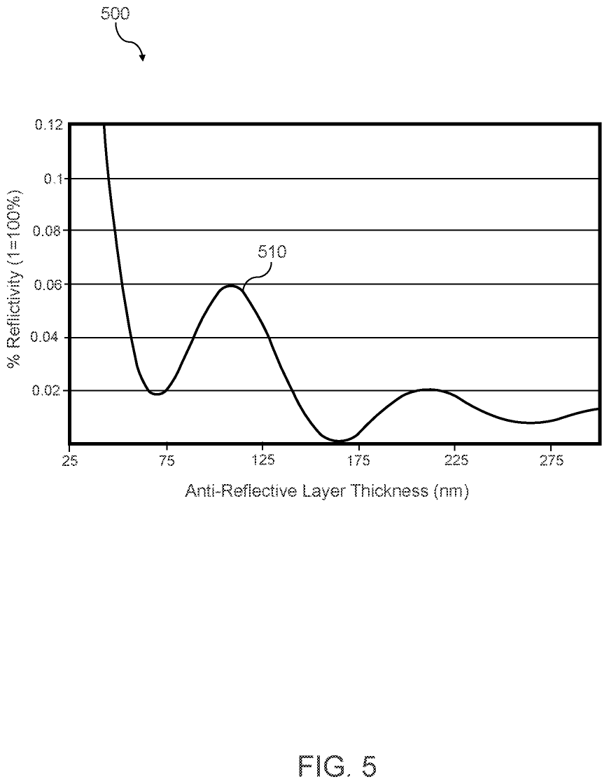

FIG. 5 depicts a graphical representation 500 of anti-reflective properties of an example anti-reflective layer as a function of thickness. FIG. 5 plots reflectivity (as a percentage where 1=100%) on the vertical axis and plots thickness of the anti-reflective layer (in nm) on the horizontal axis. Plot 510 depicts anti-reflective properties for an example anti-reflective layer (e.g., ARC i-CON™-7 manufactured by Brewer Science, Inc.). As shown, the anti-reflective layer has high reflectivity (e.g., greater than about 3%) at thicknesses in a range from about 85 nm to about 130 nm.

Example aspects of the present disclosure are set forth below. Any of the below features or examples may be used in combination with any of the embodiments or features provided in the present disclosure.

One example embodiment of the present disclosure is directed to a semiconductor structure The semiconductor structure includes an N-Polar Group III-nitride semiconductor structure and an anti-reflective layer on the N-Polar Group III-nitride semiconductor structure. The semiconductor structure includes a photoresist layer on the N-Polar Group III-nitride semiconductor structure. The anti-reflective layer has a thickness in a range of about 85 nm to about 130 nm or has a thickness of greater than about 175 nm.

In some embodiments, the anti-reflective layer has a thickness in a range of about 175 nm to about 400 nm.

In some embodiments, the anti-reflective layer comprises an organic anti-reflective layer.

In some embodiments, the anti-reflective layer has thickness associated with a reflectivity of about 3% or greater.

In some embodiments, the N-Polar Group III-nitride semiconductor structure comprise an N-polar Group III-nitride layer provided on a substrate.

In some embodiments, the substrate comprises silicon carbide.

In some embodiments, the substrate comprises a 4H-silicon carbide substrate.

Another example embodiment of the present disclosure is directed to a method for processing an N-polar Group III-nitride semiconductor structure. The method includes providing an anti-reflective layer on an N-polar Group III-nitride semiconductor structure, the N-Polar Group III-nitride semiconductor structure comprising an N-polar Group III-nitride layer. The method includes providing a photoresist layer on the anti-reflective layer. The method includes conducting a photolithography process on the N-Polar Group III-nitride semiconductor structure to pattern the photoresist layer. The anti-reflective layer has a thickness outside an anti-reflective range associated with the photolithography process.

In some embodiments, the anti-reflective layer has a thickness of from about 85 nm to about 130 nm.

In some embodiments, the anti-reflective layer has a thickness of from about 90 nm to about 110 nm.

In some embodiments, the anti-reflective layer comprises an organic anti-reflective layer.

In some embodiments, the anti-reflective layer has thickness associated with a reflectivity of about 3% or greater.

In some embodiments, the N-Polar Group III-nitride semiconductor structure comprises the N-polar Group III-nitride layer provided on a substrate.

In some embodiments, the substrate comprises silicon carbide.

In some embodiments, conducting a photolithography process on the N-Polar Group III-nitride semiconductor structure to pattern the photoresist layer, comprises: exposing the photoresist layer to radiation to pattern the photoresist layer; and developing the photoresist layer to form a photoresist pattern.

In some embodiments, the method includes etching the anti-reflective layer and the N-polar Group III-nitride layer according to the photoresist pattern.

In some embodiments, the method includes removing the photoresist layer from the photoresist pattern from the N-Polar Group III-nitride semiconductor structure.

In some embodiments, the method includes removing any remaining anti-reflective layer from the N-Polar Group III-nitride semiconductor structure.

In some embodiments, the method includes fabricating a semiconductor device at least partially in the N-polar Group III-nitride layer.

Another example embodiment of the present disclosure is directed to a method for processing an N-polar Group III-nitride semiconductor structure. The method includes providing an anti-reflective layer on an N-polar Group III-nitride semiconductor structure, the N-Polar Group III-nitride semiconductor structure comprising an N-polar Group III-nitride layer. The method includes providing a photoresist layer on the anti-reflective layer. The method includes conducting a photolithography process on the N-Polar Group III-nitride semiconductor structure to pattern the photoresist layer. The anti-reflective layer has a thickness of 85 nm to about 130 nm or has a thickness of greater than about 175 nm.

In some embodiments, the anti-reflective layer has a thickness of from about 175 nm to about 400 nm.

In some embodiments, the anti-reflective layer comprises an organic anti-reflective layer.

In some embodiments, the anti-reflective layer has thickness associated with a reflectivity of about 3% or greater.

In some embodiments, the N-Polar Group III-nitride semiconductor structure comprises the N-polar Group III-nitride layer provided on a substrate.

In some embodiments, the substrate comprises silicon carbide.

In some embodiments, conducting a photolithography process on the N-Polar Group III-nitride semiconductor structure to pattern the photoresist layer, comprises: exposing the photoresist layer to radiation to pattern the photoresist layer; and developing the photoresist layer to form a photoresist pattern.

In some embodiments, the method includes etching the anti-reflective layer and the N-polar Group III-nitride layer according to the photoresist pattern.

In some embodiments, the method includes removing any remaining photoresist layer from the photoresist pattern from the N-Polar Group III-nitride semiconductor structure.

In some embodiments, the method includes removing any remaining anti-reflective layer from the N-Polar Group III-nitride semiconductor structure.

In some embodiments, the method includes fabricating a semiconductor device at least partially in the N-polar Group III-nitride layer.

Another example embodiment of the present disclosure is directed to a semiconductor structure. The semiconductor structure includes an N-Polar Group III-nitride semiconductor structure and an anti-reflective layer on the N-Polar Group III-nitride semiconductor structure. The semiconductor structure includes a photoresist layer on the N-Polar Group III-nitride semiconductor structure. The anti-reflective layer has a thickness outside an anti-reflective range associated with the photolithography process.

In some embodiments, the anti-reflective layer has a thickness of from about 85 nm to about 130 nm.

In some embodiments, the anti-reflective layer has a thickness of from about 90 nm to about 110 nm.

In some embodiments, the anti-reflective layer comprises an organic anti-reflective layer.

In some embodiments, the anti-reflective layer has thickness associated with a reflectivity of about 3% or greater.

In some embodiments, the N-Polar Group III-nitride semiconductor structure comprises an N-polar Group III-nitride layer provided on a substrate.

In some embodiments, the substrate comprises silicon carbide.

In some embodiments, the substrate comprises a 4H-silicon carbide substrate.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. An N-Polar Group III-nitride semiconductor structure, comprising:
an N-Polar Group III-nitride semiconductor structure;
an anti-reflective layer on the N-Polar Group III-nitride semiconductor structure;
a photoresist layer on the N-Polar Group III-nitride semiconductor structure;
wherein the anti-reflective layer has a thickness in a range of about 85 nm to about 130 nm or has a thickness of about 175 nm or greater.

2. The N-Polar Group III-nitride semiconductor structure of claim 1, wherein the anti-reflective layer has a thickness in a range of about 175 nm to about 400 nm.

3. The N-Polar Group III-nitride semiconductor structure of claim 1, wherein the anti-reflective layer comprises an organic anti-reflective layer.

4. The N-Polar Group III-nitride semiconductor structure of claim 1, wherein the anti-reflective layer has thickness associated with a reflectivity of about 3% or greater.

5. The N-Polar Group III-nitride semiconductor structure of claim 1, wherein the N-Polar Group III-nitride semiconductor structure comprise an N-polar Group III-nitride layer provided on a substrate.

6. The N-Polar Group III-nitride semiconductor structure of claim 5, wherein the substrate comprises silicon carbide.

7. The N-Polar Group III-nitride semiconductor structure of claim 6, wherein the substrate comprises a 4H-silicon carbide substrate.

8. A method for processing an N-polar Group III-nitride semiconductor structure, comprising:
providing an anti-reflective layer on an N-polar Group III-nitride semiconductor structure, the N-Polar Group III-nitride semiconductor structure comprising an N-polar Group III-nitride layer;
providing a photoresist layer on the anti-reflective layer; and
conducting a photolithography process on the N-Polar Group III-nitride semiconductor structure to pattern the photoresist layer;
wherein the anti-reflective layer has a thickness outside an anti-reflective range associated with the photolithography process.

9. The method of claim 8, wherein the anti-reflective layer has a thickness of from about 85 nm to about 130 nm.

10. The method of claim 9, wherein the anti-reflective layer has a thickness of from about 90 nm to about 110 nm.

11. The method of claim 8, wherein the anti-reflective layer comprises an organic anti-reflective layer.

12. The method of claim 8, wherein the anti-reflective layer has thickness associated with a reflectivity of about 3% or greater.

13. The method of claim 8, wherein the N-Polar Group III-nitride semiconductor structure comprises the N-polar Group III-nitride layer provided on a substrate.

14. The method of claim 13, wherein the substrate comprises silicon carbide.

15. The method of claim 8, wherein conducting a photolithography process on the N-Polar Group III-nitride semiconductor structure to pattern the photoresist layer, comprises:
exposing the photoresist layer to radiation to pattern the photoresist layer; and
developing the photoresist layer to form a photoresist pattern.

16. The method of claim 15, comprising etching the anti-reflective layer and the N-polar Group III-nitride layer according to the photoresist pattern.

17. The method of claim 16, comprising removing the photoresist layer from the photoresist pattern from the N-Polar Group III-nitride semiconductor structure.

18. The method of claim 17, comprising removing any remaining anti-reflective layer from the N-Polar Group III-nitride semiconductor structure.

19. The method of claim 8, comprising fabricating a semiconductor device at least partially in the N-polar Group III-nitride layer.

20. A method for processing an N-polar Group III-nitride semiconductor structure, comprising:
providing an anti-reflective layer on an N-polar Group III-nitride semiconductor structure, the N-Polar Group III-nitride semiconductor structure comprising an N-polar Group III-nitride layer;
providing a photoresist layer on the anti-reflective layer; and
conducting a photolithography process on the N-Polar Group III-nitride semiconductor structure to pattern the photoresist layer;
wherein the anti-reflective layer has a thickness of from about 85 nm to about 130 nm or has a thickness greater than about 175 nm.

21.-38. (canceled)
